(19) United States
(12) Patent Application Publication
(10) Pub. No.: US 2023/0193465 A1
(43) Pub. Date: Jun. 22, 2023

(54) SUBSTRATE PROCESSING METHOD, METHOD OF MANUFACTURING SEMICONDUCTOR DEVICE AND SUBSTRATE PROCESSING APPARATUS

(71) Applicant: Kokusai Electric Corporation, Tokyo (JP)

(72) Inventors: Hideto TATENO, Toyama-shi (JP); Yusaku OKAJIMA, Toyama-shi (JP); Yoshinori IMAI, Toyama-shi (JP); Hiroki HATTA, Toyama-shi (JP)

(73) Assignee: Kokusai Electric Corporation, Tokyo (JP)

(21) Appl. No.: 18/171,903

(22) Filed: Feb. 21, 2023

Related U.S. Application Data
(63) Continuation of application No. PCT/JP20/36075, filed on Sep. 24, 2020.

(51) Int. Cl. C23C 16/458; C23C 16/52; C23C 16/455

(52) U.S. Cl. CPC C23C 16/4588; C23C 16/52; C23C 16/455

(57) ABSTRACT

According to one aspect of the technique of the present disclosure, there is provided a substrate processing method including: accommodating a substrate retainer in a process chamber, including: a substrate support; and a partition plate support capable of supporting an upper partition plate provided above a substrate supported by the substrate support; setting a distance between the substrate and the upper partition plate to a first gap; supplying a first gas to the substrate through a gas supply port in a state where the distance between the substrate and the upper partition plate is maintained at the first gap; setting the distance between the substrate and the upper partition plate to a second gap; and supplying a second gas to the substrate through the gas supply port in a state where the distance between the substrate and the upper partition plate is maintained at the second gap.

### CROSS-REFERENCE TO RELATED PATENT APPLICATION

This application is a bypass continuation application of PCT International Application No. PCT/JP2020/036075, filed on Sep. 24, 2020, in the WIPO, the entire contents of which are hereby incorporated by reference.

### BACKGROUND

### 1. Field

The present disclosure relates to a substrate processing method, a method of manufacturing a semiconductor device and a substrate processing apparatus.

### 2. Related Art

In a heat treatment process of a substrate (also referred to as a “wafer”) in a manufacturing process of a semiconductor device, the substrate is supported by a substrate retainer, and the substrate retainer is loaded into a process chamber. Thereafter, a process gas is introduced into the process chamber while the process chamber is heated to perform a film-forming process on the substrate. For example, according to some related arts, it is described that a nitride film is formed on a pattern including a recess formed on a surface of the substrate by repeatedly performing: (a) nitriding a first layer formed by supplying a source gas to form NH terminations; and (b) modifying some of the NH terminations to form N terminations by performing a plasma process, so as to improve filling characteristics of the nitride film in the recess.

### SUMMARY

According to the present disclosure, there is provided a technique capable of improving a step coverage of a film formed on a formation pattern on a substrate.

According to one aspect of the technique of the present disclosure, there is provided a substrate processing method including: (a) accommodating a substrate retainer in a process chamber, wherein the substrate retainer includes: a substrate support capable of supporting a substrate; and a partition plate support capable of supporting an upper partition plate provided above the substrate supported by the substrate support; (b) setting a distance between the substrate and the upper partition plate to a first gap; (c) supplying a first gas to the substrate through a gas supply port in a state where the distance between the substrate and the upper partition plate is maintained at the first gap; (d) setting the distance between the substrate and the upper partition plate to a second gap; and (e) supplying a second gas to the substrate through the gas supply port in a state where the distance between the substrate and the upper partition plate is maintained at the second gap.

### BRIEF DESCRIPTION OF THE DRAWINGS

FIG. 1 is a cross-sectional view of a process chamber and a storage chamber schematically illustrating a state in which a boat in which a plurality of substrates are accommodated is transferred into a transfer chamber of a substrate processing apparatus preferably used in one or more embodiments of the present disclosure.

FIG. 2 is a cross-sectional view of the process chamber and the storage chamber schematically illustrating a state in which the boat in which the plurality of substrates are accommodated is elevated and transferred into the process chamber of the substrate processing apparatus preferably used in the embodiments of the present disclosure.

FIGS. 3A through 3C are cross-sectional views of a substrate and a partition plate schematically illustrating a distance between the substrate and the partition plate in the process chamber of the substrate processing apparatus preferably used in the embodiments of the present disclosure.

FIG. 4 is a graph schematically illustrating a distribution of a concentration of a material gas on a surface of the substrate when the distance between the substrate and the partition plate is switched (or alternately changed) in the process chamber of the substrate processing apparatus preferably used in the embodiments of the present disclosure.

FIG. 5 is a perspective view of the substrate schematically illustrating the distribution of the concentration of the material gas on the surface of the substrate when the distance between the substrate and the partition plate is set to a long distance as shown in FIG. 3C, along with a diagram schematically visualizing the distribution of the concentration of the material gas on the surface of the substrate in the process chamber of the substrate processing apparatus preferably used in the embodiments of the present disclosure.

FIG. 6 is a block diagram schematically illustrating an exemplary configuration of a controller and related components of the substrate processing apparatus preferably used in the embodiments of the present disclosure.

FIG. 7A is a flow chart schematically illustrating a manufacturing process of a semiconductor device according to the embodiments of the present disclosure.

FIG. 7B is a detailed flow chart illustrating details of a step S705 shown in the flow chart of FIG. 7A.

FIG. 8 is a table schematically illustrating an exemplary list of items in a process recipe read by a CPU of the substrate processing apparatus according to the embodiments of the present disclosure.

FIG. 9 is a cross-sectional view of a pattern of a trench structure formed in the substrate preferably used in the embodiments of the present disclosure.

FIG. 10 is a cross-sectional view of the pattern of the trench structure formed in the substrate preferably used in the embodiments of the present disclosure, in a state where a layer containing silicon (Si) is formed on the surface of the substrate including an inside of the pattern of the trench structure.

FIG. 11 is a cross-sectional view of the pattern of the trench structure formed in the substrate preferably used in the embodiments of the present disclosure, in a state where a first layer is formed on the surface of the substrate including the inside of the pattern of the trench structure.

FIG. 12 is a cross-sectional view of the pattern of the trench structure formed in the substrate preferably used in the embodiments of the present disclosure, in a state where chorine (Cl) terminations are formed on a part of the first layer formed on the substrate including the inside of the pattern of the trench structure.

FIG. 13 is a cross-sectional view of the pattern of the trench structure formed in the substrate preferably used in the embodiments of the present disclosure, in a state where a second layer is formed by being laminated after the Cl terminations are formed on the part of the first layer formed on the substrate including the inside of the pattern of the trench structure.

### DETAILED DESCRIPTION

The present disclosure relates to forming a film with an improved step coverage along a pattern by using a substrate processing apparatus including: a boat in which a plurality of substrates are accommodated; a plurality of partition plates configured separately from the boat and provided above the plurality of substrates accommodated in the boat, respectively; and an elevator configured to alternately change (or switch) a positional relationship between the plurality of substrates and the plurality of partition plates in a vertical direction. During a film-forming process, by alternately changing (or switching) a gap between each partition plate and its adjacent substrate and alternately changing (or switching) a type of a gas to be supplied, it is possible to form the film with the good step coverage with respect to the pattern.

Hereinafter, one or more embodiments (also simply referred to as “embodiments”) according to the technique of the present disclosure will be described with reference to the drawings. In the drawings for explaining the embodiments, like reference numerals represent like components, and redundant descriptions related thereto will be omitted in principle. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

However, the technique of the present disclosure is not construed as being limited to the contents of the embodiments described below. Those skilled in the art will easily understand that specific configurations of the technique of the present disclosure can be changed without departing from the idea and the purpose of the technique of the present disclosure.

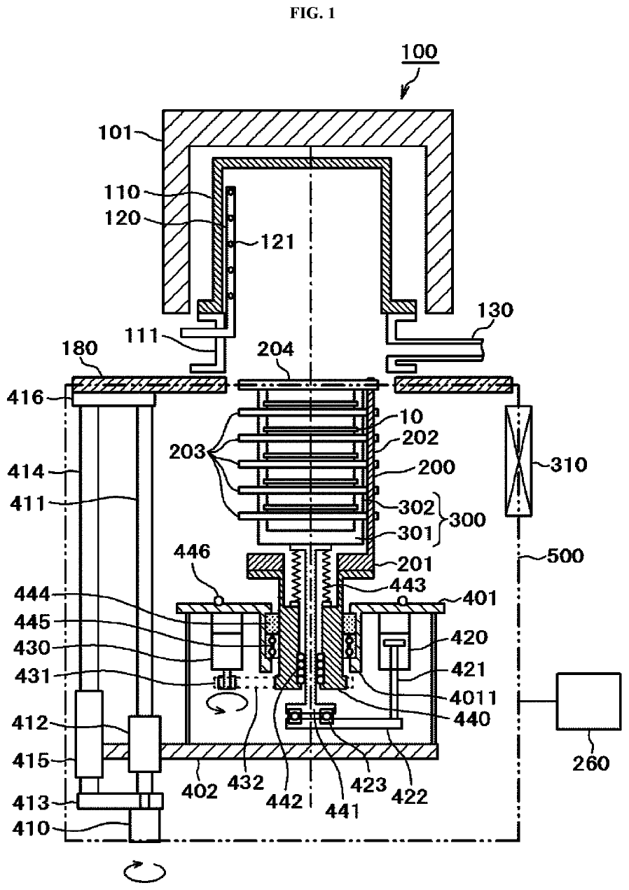

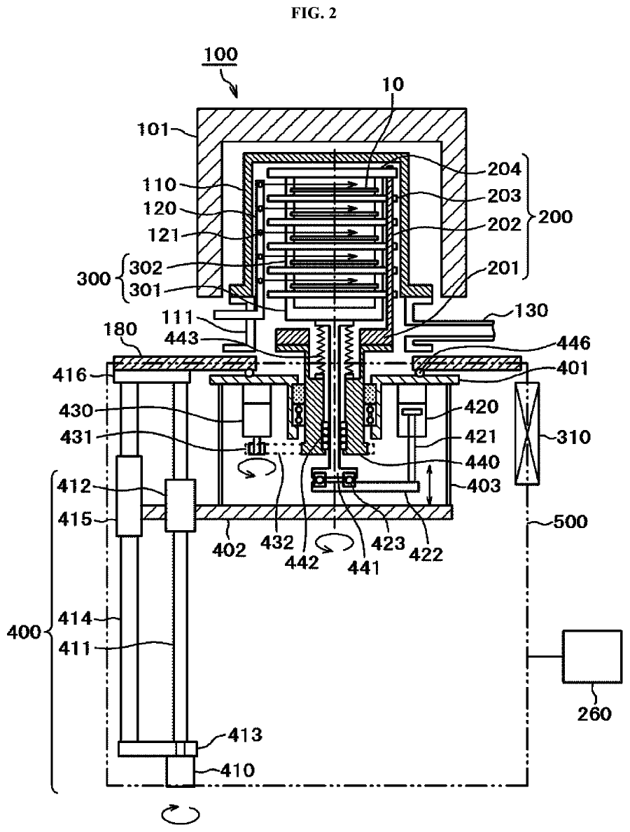

A configuration of the substrate processing apparatus according to the embodiments of the technique of the present disclosure will be described with reference to FIGS. 1 and 2.

<Substrate Processing Apparatus 100>

The substrate processing apparatus 100 includes: a reaction tube 110 of a cylindrical shape extending in the vertical direction; a heater 101 serving as a heating structure (furnace body) installed on an outer periphery of the reaction tube 110; and a gas supply nozzle 120 constituting a gas supplier (which is a gas supply structure or a gas supply system). For example, the heater 101 is constituted by a zone heater which is vertically divided into a plurality of heater structures (blocks) and a temperature of each heater structure can be set individually.

For example, the reaction tube 110 is made of a material such as quartz and silicon carbide (SiC). A process chamber is defined by the reaction tube 110. An inner atmosphere of the reaction tube 110 is exhausted by an exhaust component (not shown) through an exhaust pipe 130 constituting an exhauster (which is an exhaust structure or an exhaust system). An inside of the reaction tube 110 is hermetically sealed with respect to an outside air by a component such as a seal (not shown).

The technique of the present disclosure can also be applied even when a second reaction tube (not shown) is provided inside of the reaction tube 110 described herein.

The gas supply nozzle (hereinafter, also simply referred to as a “nozzle”) 120 is provided with a plurality of holes including a hole 121 through which a gas is supplied into the reaction tube 110. Hereinafter, the plurality of holes including the hole 121 may also be referred to as “holes 121”. Further, the hole 121 may also be referred to as a “gas supply port 121”.

A source gas, a reactive gas and an inert gas (which is a carrier gas) are introduced into the reaction tube 110 through the holes 121 provided at the gas supply nozzle 120.

Flow rates of the source gas, the reactive gas and the inert gas (carrier gas) supplied from a source gas supply source (not shown), a reactive gas supply source (not shown) and an inert gas supply source (not shown), respectively, are adjusted by mass flow controllers (MFCs) (not shown), respectively, and then are supplied into the reaction tube 110 through the holes 121 provided at the nozzle 120.

The inner atmosphere of the reaction tube 110 is vacuum-exhausted by the exhaust component (not shown) through the exhaust pipe 130 provided at a manifold 111.

<Chamber 180>

A chamber 180 is provided under the reaction tube 110 via the manifold 111, and includes a storage chamber 500. In the storage chamber 500, a substrate 10 may be placed (mounted) on a substrate support (which is a substrate support portion or a boat) 300 by a transfer device (not shown) via a substrate loading/unloading port 310, or the substrate 10 is transferred from the substrate support 300 by the transfer device.

In the present embodiments, the chamber 180 is made of a metal material such as stainless steel (SUS) and aluminum (Al).

Inside the chamber 180 is provided a vertical driver 400 constituting a first driver capable of driving the substrate support 300, a partition plate support 200 or both of the substrate support 300 and the partition plate support 200 (collectively referred to as a “substrate retainer”) in the vertical direction and a rotational direction.

<Substrate Support Structure>

A substrate support structure is constituted by at least the substrate support 300. The substrate 10 is transferred into the storage chamber 500 by the transfer device (not shown) via the substrate loading/unloading port 310, and a process of forming a film on a surface of the substrate 10 is performed on the substrate 10 by further transferring the substrate 10 into the reaction tube 110. In addition, the substrate support structure may further include the partition plate support 200.

As shown in FIGS. 1 and 2, in the partition plate support 200, a plurality of partition plates including a partition plate 203 of a disk shape are fixed at a predetermined pitch to a support column 202 supported between a base 201 and a top plate 204. Hereinafter, the plurality of partition plates including the partition plate 203 may also be referred to as “partition plates 203”. As shown in FIGS. 1 and 2, the substrate support 300 includes a configuration in which a plurality of support rods 302 are supported at a base 301, and the plurality of substrates including the substrate 10 are supported by the plurality of support rods 302 at a predetermined interval. Hereinafter, the plurality of substrates including the substrate 10 may also be referred to as “substrates 10”.

In the substrate support 300, the plurality of substrates 10 are placed at the predetermined interval by the plurality of support rods 302 supported at the base 301. The plurality of substrates 10 supported by the plurality of support rods 302 are partitioned by the plurality of partition plates 203 of a disk shape fixed (supported) to the support columns 202 supported by the partition plate support 200 at a predetermined interval. According to the present embodiments, the partition plate 203 is arranged on either one or both of an upper portion and a lower portion of the substrate 10.

The predetermined interval between the plurality of substrates 10 accommodated in the substrate support 300 is the same as a vertical interval between two adjacent ones of the partition plates 203 fixed to the partition plate support 200. Further, a diameter of the partition plate 203 is set to be greater than a diameter of the substrate 10.

The substrate support 300 is configured to support the substrates (for example, five substrates to 50 substrates) 10 by the plurality of support rods 302 in a multistage manner in the vertical direction. For example, a vertical interval (distance) between the substrates 10 supported in a multistage manner in the vertical direction is set to an interval within a range from about 40 mm to 70 mm. For example, the base 301 and the plurality of support rods 302, which constitute the substrate support 300, are made of a material such as quartz and SiC. Further, the partition plates 203 of the partition plate support 200 may also be referred to as “separators”.

The partition plate support 200 and the substrate support 300 are moved (driven) by the vertical driver 400 in the vertical direction between the reaction tube 110 and the storage chamber 500 and in the rotational direction around a center of the substrate 10 supported by the substrate support 300.

As shown in FIGS. 1 and 2, the vertical driver 400 constituting the first driver includes a vertical driving motor 410, a rotational driving motor 430, which serve as driving sources, and a boat vertical driver 420 provided with a linear actuator serving as a substrate support elevator capable of driving the substrate support 300 in the vertical direction.

The vertical driving motor 410 serving as a partition plate support elevator is configured to rotationally drive a ball screw 411 to move a nut 412 screwed to the ball screw 411 in the vertical direction along the ball screw 411. As a result, the partition plate support 200 and the substrate support 300 are driven in the vertical direction between the reaction tube 110 and the storage chamber 500 together with a base plate 402 fixing the nut 412. The base plate 402 is also fixed to a ball guide 415 engaged with a guide shaft 414, and is configured to be capable of moving smoothly in the vertical direction along the guide shaft 414. Upper ends and lower ends of the ball screw 411 and the guide shaft 414 are fixed to fixing plates 413 and 416, respectively. In addition, the partition plate support elevator may include a structure for transmitting the power of the vertical driving motor 410.

The rotational driving motor 430 and the boat vertical driver 420 provided with the linear actuator constitute a second driver, and are fixed to a base flange 401 serving as a lid supported by a side plate 403 at the base plate 402. By using the side plate 403, it is possible to suppress a diffusion of particles generated by a component such as a vertical driver such as the boat vertical driver 420 and a rotator (which is a rotating structure) such as the rotational driving motor 430. The side plate 403 is of a cover shape (in a cylindrical shape or a columnar shape) so as to cover the component such as the vertical driver and the rotator. A hole (not shown) through which a transfer chamber is in communication with the side plate 403 of the cover shape is provided at the side plate 403 on a part of the side plate 403 or on a bottom surface of the side plate 403. By the hole through which the transfer chamber is in communication with the side plate 403 of the cover shape, an inner pressure of the side plate 403 of the cover shape can be set to be substantially equal to an inner pressure of the transfer chamber.

On the other hand, a support column may be used instead of the side plate 403. In such a case, it is possible to easily perform a maintenance operation on the component such as the vertical driver and the rotator.

The rotational driving motor 430 is configured to drive a rotation transmission belt 432 engaging with a tooth portion 431 attached to a front end (tip) of the rotational driving motor 430, and to rotate (rotationally drive) a support 440 engaging with the rotation transmission belt 432. The support 440 is configured to support the partition plate support 200 by the base 201, and to be driven by the rotational driving motor 430 via the rotation transmission belt 432 to rotate the partition plate support 200 and the substrate support 300.

The support 440 is separated from an inner cylinder portion 4011 of the base flange 401 by a vacuum seal 444, and a lower portion thereof is rotatably guided with respect to the inner cylinder portion 4011 of the base flange 401 by a bearing 445.

The boat vertical driver 420 provided with the linear actuator is configured to drive a shaft 421 in the vertical direction. A plate 422 is attached to a front end (tip) of the shaft 421. The plate 422 is connected to a support structure 441 fixed to the base 301 of the substrate support (boat) 300 via a bearing 423. By connecting the support structure 441 to the plate 422 via the bearing 423, it is possible to rotate the substrate support (boat) 300 together with the partition plate support 200 when the partition plate support 200 is rotated (rotationally driven) by the rotational driving motor 430.

On the other hand, the support structure 441 is supported by the support 440 via a linear guide bearing 442. With such a configuration, when the shaft 421 is driven in the vertical direction by the boat vertical driver 420 provided with the linear actuator, it is possible to drive the support structure 441 fixed to the substrate support 300 relatively in the vertical direction with respect to the support 440 fixed to the partition plate support 200.

By configuring the support 440 and the support structure 441 into a concentric structure as described above, it is possible to simplify a structure of the rotator using the rotational driving motor 430. Further, it is possible to easily control a synchronization of a rotation between the substrate support 300 and the partition plate support 200.

However, the present embodiments are not limited thereto, and the support 440 and the support structure 441 may be arranged separately rather than concentrically.

The support 440 fixed to the partition plate support 200 and the support structure 441 fixed to the substrate support 300 are connected by a vacuum bellows 443.

An O-ring 446 for vacuum sealing is installed on an upper surface of the base flange 401 serving as the lid, and as shown in FIG. 2, by driving the vertical driving motor 410 to elevate the upper surface of the base flange 401 to a position where the upper surface of the base flange 401 is pressed against the chamber 180, it is possible to airtightly maintain the inside of the reaction tube 110.

The O-ring 446 for vacuum sealing may be omitted, and by pressing the upper surface of the base flange 401 against the chamber 180 without using the O-ring 446 for vacuum sealing, it is possible to airtightly maintain the inside of the reaction tube 110. Further, the vacuum bellows 443 may be omitted.

In the configuration described above, by driving the vertical driving motor 410 to elevate the upper surface of the base flange 401 until the upper surface of the base flange 401 is pressed against the chamber 180 as shown in FIG. 2 such that the substrate support structure is inserted into the reaction tube 110, the source gas, the reactive gas or the inert gas (carrier gas) is introduced into the reaction tube 110 through the holes 121 provided at the gas supply nozzle 120.

A pitch of the holes 121 provided at the gas supply nozzle 120 is substantially the same as the vertical interval of the substrates 10 accommodated in the substrate support 300 and the vertical pitch (interval) of the partition plates 203 fixed to the partition plate support 200. Further, a plurality of nozzles may be inserted from a lateral direction (a horizontal direction with respect to the substrate 10) to supply the gas to each of the plurality of substrates 10.

According to the present embodiments, in a state where the upper surface of the base flange 401 is pressed against the chamber 180, a height position (that is, a position in the vertical direction) of the partition plates 203 fixed to the support column 202 of the partition plate support 200 is fixed, and a height position of the substrate 10, supported by the substrate support 300, with respect to the partition plate 203 may be changed by operating the boat vertical driver 420 provided with the linear actuator so as to elevate or lower the support structure 441 fixed to the base 301 of the substrate support 300. Since a position of the hole 121 provided at the gas supply nozzle 120 is also fixed, a height position (relative position) of the substrate 10, supported by the substrate support 300, with respect to the hole 121 may also be changed.

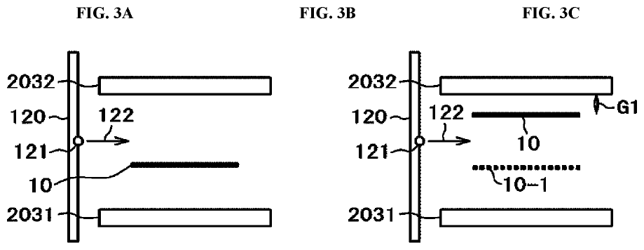

That is, by adjusting the position (height position) of the substrate 10 supported by the substrate support 300 in the vertical direction by operating the boat vertical driver 420 provided with the linear actuator with respect to a reference positional relationship of a transfer operation as shown in FIG. 3A, it is possible to adjust positional relationships of the substrate 10 with respect to the hole 121 provided at the nozzle 120 and the partition plate 203 such that a distance between the substrate 10 and a partition plate (also referred to as an “upper partition plate”) 2032 above the substrate 10 is narrowed (that is, a narrowed gap G1 is formed between the upper partition plate 2032 and the substrate 10) as shown in FIG. 3B by setting a position of the substrate 10 to be higher than a transfer position (home position) 10-1, or such that the distance between the upper partition plate 2032 and the substrate 10 is widened (that is, a widened gap G2 is formed between the upper partition plate 2032 and the substrate 10) as shown in FIG. 3C by setting the position of the substrate 10 to be lower than the transfer position (home position) 10-1.

By changing the position of the substrate 10 with respect to the hole 121 provided at the nozzle 120 as described above, it is possible to change a positional relationship between a gas flow 122 ejected through the hole 121 and the substrate 10.

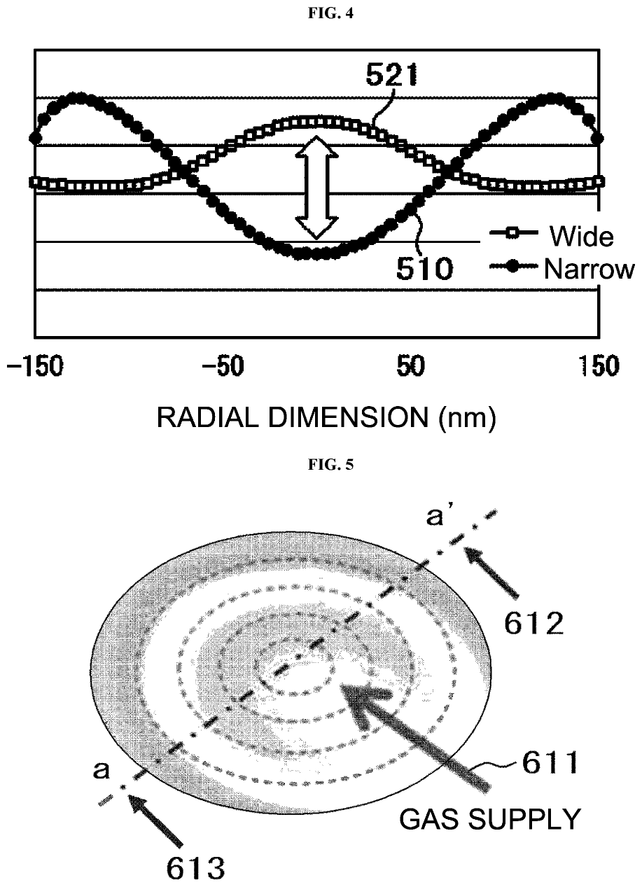

FIG. 4 schematically illustrates a simulation result of a distribution of the film formed on the surface of the substrate 10 (or a distribution of a concentration of a material gas on the surface of the substrate 10) when the gas is supplied through the hole 121 provided at the nozzle 120 in a state in which the position of the substrate 10 is elevated to form the narrowed gap G1 between the substrate 10 and the upper partition plate 2032 as shown in FIG. 3B and in a state in which the position of the substrate 10 is lowered to form the widened gap G2 between the substrate 10 and the upper partition plate 2032 as shown in FIG. 3C.

A point sequence 510 indicated by “Narrow” in FIG. 4 schematically illustrates a case where the film is formed in the state shown in FIG. 3B, that is, the state in which the position of the substrate 10 is elevated to form the narrowed gap G1 between the substrate 10 and the upper partition plate 2032, and the position of the substrate 10 is set to be higher than a position of the gas flow 122 ejected through the hole 121. In such a case, a relatively thick film is formed on a peripheral portion of the substrate 10. As a result, it is possible to obtain a concave thickness distribution of the film in which a thickness of the film formed on a central portion of the substrate 10 is thinner than that of the film formed on the peripheral portion of the substrate 10.

On the other hand, a point sequence 521 indicated by “Wide” in FIG. 4 schematically illustrates a case where the film is formed in the state shown in FIG. 3C, that is, the state in which the position of the substrate 10 is lowered to form the widened gap G2 between the substrate 10 and the upper partition plate 2032, and the position of the substrate 10 is set to be lower than the position of the gas flow 122 ejected through the hole 121. In such a case, it is possible to obtain a convex thickness distribution of the film in which the film is relatively thicker on the central portion of the substrate 10 than on the peripheral portion of the substrate 10.

It can be seen that, by changing the position of the substrate 10 as described above, the distribution of the film formed on the surface of the substrate 10 can be changed.

FIG. 5 schematically illustrates a simulation result of a distribution of a partial pressure of the gas (or the distribution of the concentration of the material gas) on the surface of the substrate 10 when the gas is supplied along a direction of an arrow 611 in a case where the positional relationships of the substrate 10 with respect to the upper partition plate 2032 and the hole 121 provided at the nozzle 120 are set as shown in FIG. 3C. The thickness distribution of the film in FIG. 4 corresponds to the thickness distribution of the film in a cross-section taken along the line a-a of FIG. 5.

As shown in FIG. 5, when the positional relationships of the substrate 10 with respect to the upper partition plate 2032 and the hole 121 provided in the nozzle 120 are set as shown in FIG. 3C, the partial pressure of the gas is relatively high in portions illustrated in dark color on the substrate 10 extending from a portion close to the hole 121 provided at the nozzle 120 to the central portion of the substrate 10. On the other hand, the partial pressure of the gas is relatively low in the peripheral portion of the substrate 10 located far from the hole 121 provided at the nozzle 120.

In such a state, by rotationally driving the support 440 by driving the rotational driving motor 430 so as to rotate the partition plate support 200 and the substrate support 300, the substrate 10 accommodated in the substrate support 300 is rotated. Thereby, it is possible to reduce a variation in the thickness of the film (in the thickness distribution of the film) in a circumferential direction of the substrate 10.

<Controller>

As shown in FIG. 1, the substrate processing apparatus 100 is connected to a controller 260 configured to control operations of components of the substrate processing apparatus 100.

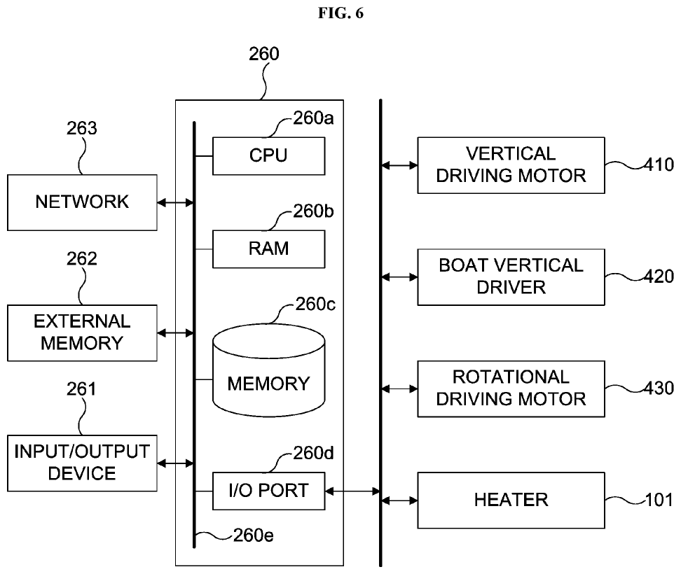

The controller 260 is schematically illustrated in FIG. 6. The controller 260 serving as a control apparatus (control structure) is constituted by a computer including a CPU (Central Processing Unit) 260a, a RAM (Random Access Memory) 260b, a memory 260c and an I/O port 260d. The RAM 260b, the memory 260c and the I/O port 260d may exchange data with the CPU 260a through an internal bus 260e. For example, an input/output device 261 configured by a component such as a touch panel and an external memory 262 may be connected to the controller 260.

The memory 260c is configured by a component such as a flash memory, a hard disk drive (HDD) and a solid state drive (SSD). For example, a control program configured to control the operations of the substrate processing apparatus 100, a process recipe containing information on sequences and conditions of a substrate processing described later, or a database may be readably stored in the memory 260c.

The process recipe is obtained by combining steps of the substrate processing described later such that the controller 260 can execute the steps to acquire a predetermined result, and functions as a program.

Hereafter, the process recipe and the control program may be collectively or individually referred to as a “program”. Thus, in the present specification, the term “program” may refer to the process recipe alone, may refer to the control program alone, or may refer to both of the process recipe and the control program. In addition, the RAM 260b functions as a memory area (work area) where a program or data read by the CPU 260a is temporarily stored.

The I/O port 260d is electrically connected to the components such as the substrate loading/unloading port 310, the vertical driving motor 410, the boat vertical driver 420 provided with the linear actuator, the rotational driving motor 430, the heater 101, the mass flow controllers (not shown), a temperature regulator (not shown) and a vacuum pump (not shown).

In addition, in the present disclosure, “electrically connected” means that the components are connected by physical cables or the components are capable of communicating with one another to transmit and receive signals (electronic data) to and from one another directly or indirectly. For example, a device for relaying the signals or a device for converting or computing the signals may be provided between the components.

The CPU 260a is configured to read and execute the control program from the memory 260c and read the process recipe from the memory 260c in accordance with an instruction such as an operation command inputted from the controller 260. The CPU 260a is configured to be capable of controlling various operations in accordance with the contents of the read process recipe such as an opening and closing operation of the substrate loading/unloading port 310, a driving operation of the vertical driving motor 410, a driving operation of the boat vertical driver 420 provided with the linear actuator, a rotating operation of the rotational driving motor 430 and an operation of supplying electrical power to the heater 101.

The controller 260 is not limited to a dedicated computer, and the controller 260 may be embodied by a general-purpose computer. For example, the controller 260 according to the present embodiments may be embodied by preparing the external memory 262 (e.g., a magnetic tape, a magnetic disk such as a flexible disk and a hard disk, an optical disk such as a CD and a DVD, a magneto-optical disk such as an MO, a semiconductor memory such as a USB memory, the SSD and a memory card) in which the above-described program is stored, and by installing the program onto the general-purpose computer using the external memory 262.

A method of providing the program to the computer is not limited to the external memory 262. For example, the program may be directly provided to the computer by a communication instrument such as a network 263 (the Internet and a dedicated line) instead of the external memory 262. The memory 260c and the external memory 262 may be embodied by a non-transitory computer-readable recording medium. Hereinafter, the memory 260c and the external memory 262 are collectively or individually referred to as a recording medium. Thus, in the present specification, the term “recording medium” may refer to the memory 260c alone, may refer to the external memory 262 alone, or may refer to both of the memory 260c and the external memory 262.

<Substrate Processing (Film-forming Process)>

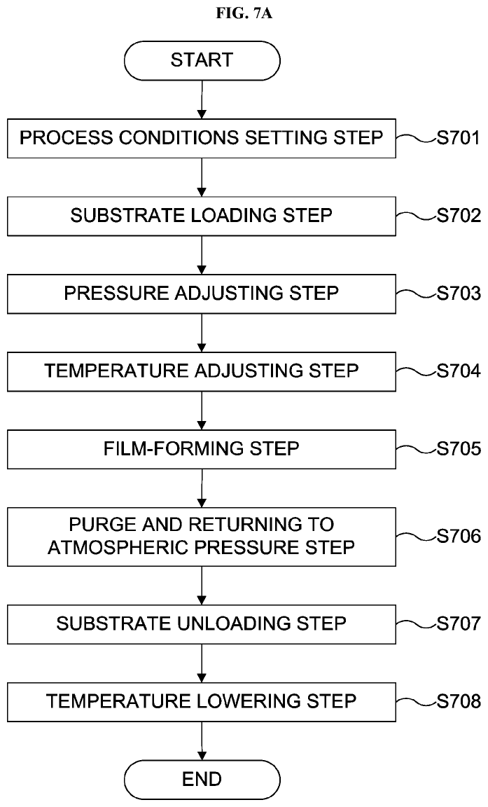

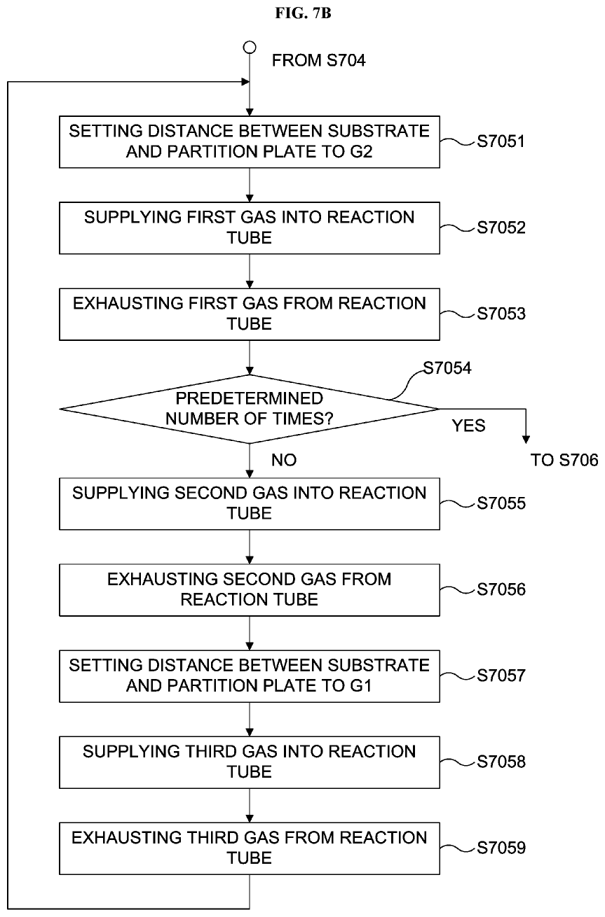

Hereinafter, the substrate processing (film-forming process) of forming the film on the substrate 10 by using the substrate processing apparatus 100 described with reference to FIGS. 1 and 2 will be described with reference to FIGS. 7A, 7B, 8 through 13.

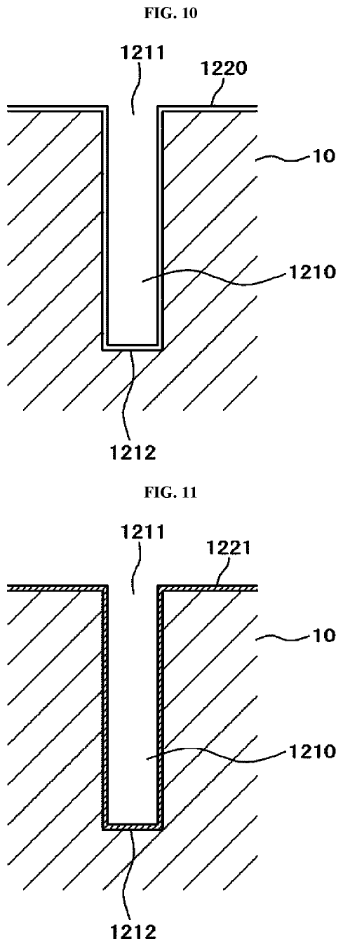

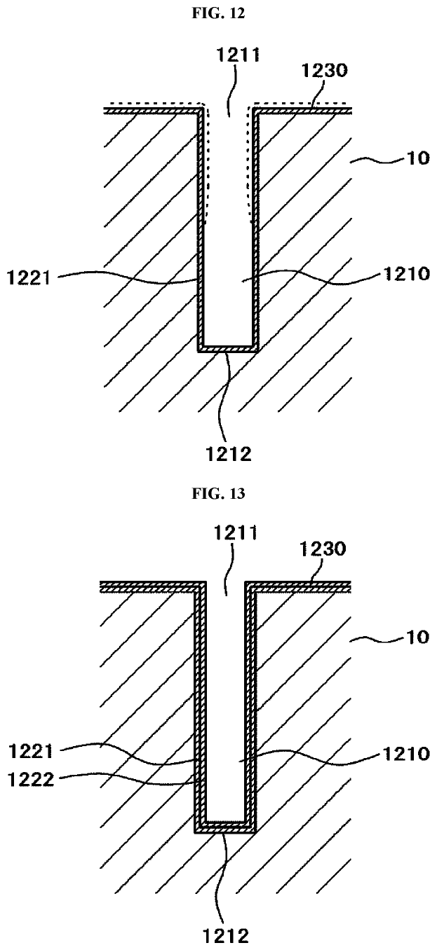

The technique of the present disclosure can be applied to one or both of the film-forming process and an etching process. However, by applying the technique of the present disclosure as a part of a manufacturing process of a semiconductor device, a first layer 1220 as shown in FIG. 10 is formed on a surface of a pattern 1210 (hereinafter, may also be simply referred to as a “trench 1210”) of a trench structure formed on the substrate 10 as shown in FIG. 9. Further, the first layer 1220 contains an element contained in the source gas. Subsequently, by causing the reactive gas to react with the first layer 1220, a second layer 1221 containing NH terminations is formed on a surface of the first layer 1220 as shown in FIG. 11. The second layer 1221 contains the element contained in the sources gas and an element contained in the reactive gas. Further, as shown in FIG. 12, chlorine (Cl) terminations 1230 are formed at a part of the NH terminations. Thereafter, as shown in FIG. 13, a third layer 1222 is newly formed by being stacked on the second layer 1221 (wherein the NH terminations are formed on a surface thereof and partially covered with the Cl terminations 1230). Further, the third layer 1222 contains the element contained in the source gas. In addition, a method of repeatedly performing a step of forming the NH terminations on a surface thereof and a step of forming the Cl terminations on a part of the NH terminations for a predetermined number of times will be described.

The process of forming the film containing silicon (Si) on the substrate 10 and the step of forming the NH terminations or the Cl terminations on the surface of the film formed on the substrate 10 are performed inside the reaction tube 110 of the substrate processing apparatus 100 described above. As described above, by executing the program by the CPU 260a of the controller 260 of FIG. 6, the manufacturing process is performed.

In the substrate processing (the manufacturing process of the semiconductor device) according to the present embodiments, first, by driving the vertical driving motor 410 to elevate the upper surface of the base flange 401 until the upper surface of the base flange 401 is pressed against the chamber 180 as shown in FIG. 2, the substrate support structure is inserted into the reaction tube 110.

Subsequently, in such a state, by driving the shaft 421 in the vertical direction by the boat vertical driver 420 provided with the linear actuator, the height (distance) of the substrate 10 (which is accommodated in the substrate support 300) with respect to the partition plate 203 can be set from an initial state shown in FIG. 3A to a state in which the substrate 10 is lowered to a position lower than the transfer position (home position) 10-1, as shown in 3C, such that the distance between the partition plate 203 and the substrate 10 is widened, that is, the widened gap G2 is formed between the partition plate 203 and the substrate 10. By setting the position of the substrate 10 to a position lower than the gas supply port 121 provided at the nozzle 120 as described above, the height of the substrate 10 with respect to the partition plate 203 (which is the distance between the substrate 10 and the partition plate 203) is adjusted to a first desired value.

In such a state, (a) a step of forming a layer containing silicon (Si) on the surface of the substrate 10 and an inside of the pattern 1210 of the trench structure by supplying the source gas through the gas supply nozzle 120 to the substrate 10 accommodated in the reaction tube 110 and (b) a step of removing a residual gas including the source gas in the reaction tube 110 are performed.

As described above, the layer containing silicon is formed on the surface of the substrate 10 by supplying the source gas. When forming the layer containing silicon, since the distance between the substrate 10 and the partition plate 203 is set to be relatively large (that is, the widened gap G2), a flow velocity of the source gas flowing between the substrate 10 and the partition plate 203 becomes relatively slow. As a result, the source gas is supplied to the vicinity of a bottom portion 1212 of the pattern 1210 of the trench structure, and as shown in FIG. 10, the first layer 1220 is formed on the surface (of the substrate 10) including the bottom portion 1212 of the pattern 1210 of the trench structure by the source gas. Further, the first layer 1220 contains the element contained in the source gas.

Subsequently, in a state where the distance between the substrate 10 and the partition plate 203 is maintained at the widened gap G2, (c) a step of supplying the reactive gas from the gas supply nozzle 120 to the substrate 10 accommodated in the reaction tube 110 and causing the reactive gas to react with the first layer 1220 formed by the source gas and (d) a step of removing a residual gas including the reactive gas in the reaction tube 110 are performed.

By supplying the reactive gas in a heated state to the surface of the substrate 10 on which the first layer 1220 is formed by the source gas and causing the reactive gas to react with the first layer 1220, the second layer 1221 containing the NH terminations is formed on the surface of the first layer 1220. Further, the second layer 1221 contains the element contained in the sources gas and the element contained in the reactive gas.

When forming the second layer 1221, since the distance between the substrate 10 and the partition plate 203 is maintained at the widened gap G2 in the same manner as when the source gas is supplied, the reactive gas is supplied to the vicinity of the bottom portion 1212 in the pattern 1210 of the trench structure in the same manner as when the source gas is supplied, and as shown in FIG. 10, the NH terminations are also formed on the surface of the first layer 1220 formed on the surface (of the substrate 10) including the bottom portion 1212 of the pattern 1210 of the trench structure.

Subsequently, in a state where the substrate 10 is elevated to a position higher than the transfer position (home position) 10-1 and the distance between the substrate 10 and the partition plate 203 is maintained at the narrowed gap G1 (which is narrower than the widened gap G2), (e) a step of supplying a film-forming inhibitory gas from the gas supply nozzle 120 to the substrate 10 and replacing a part of the NH terminations formed on the surface of the first layer 1220 formed by the source gas with the Cl terminations 1230 and (f) a step of removing a residual gas including the film-forming inhibitory gas in the reaction tube 110 are performed.

When supplying the film-forming inhibitory gas, since the distance between the substrate 10 and the partition plate 203 is set to is set to the narrowed gap G1 (which is narrower than the widened gap G2 when the source gas or the reactive gas is supplied), a flow velocity of the film-forming inhibitory gas flowing between the substrate 10 and the partition plate 203 becomes fast.

As a result, as shown in FIG. 12, the Cl terminations 1230 are formed on the surface of the substrate 10 and in the vicinity of an entrance portion 1211 of the pattern 1210 of the trench structure. On the other hand, since the flow velocity thereof is high, the film-forming inhibitory gas does not reach the bottom portion 1212 of the pattern 1210 of the trench structure. Thus, on the bottom portion 1212 of the pattern 1210 of the trench structure and its vicinity, the Cl terminations 1230 are not formed and therefore the NH terminations are exposed.

The Cl terminations 1230 acts as a film-forming inhibitory layer (or an adsorption inhibitory layer), that is, an inhibitor with respect to the third layer 1222 formed by the source gas. As a result, when the third layer 1222 is formed on the surface of the substrate 10 including a portion where the Cl terminations 1230 are formed, a film-forming rate (deposition rate) of the third layer 1222 in the portion where the Cl terminations 1230 are formed is slower than that of the third layer 1222 in a portion where the Cl terminations 1230 are not formed and therefore the second layer 1221 is exposed. Further, the third layer 1222 contains the element contained in the source gas.

In addition, the film-forming inhibitory layer may also be referred to as the “inhibitor”, or the film-forming inhibitory gas itself supplied to the substrate 10 to form the film-forming inhibitory layer may also be referred to as the “inhibitor”. Thus, in the present specification, the term “inhibitor” may refer to the film-forming inhibitory layer alone, may refer to the film-forming inhibitory gas alone, or may refer to both of the film-forming inhibitory layer and the film-forming inhibitory gas.

As a result, as shown in FIG. 13, without reducing the film-forming rate of the third layer 1222 in the vicinity of the bottom portion 1212 of the pattern 1210 of the trench structure, it is possible to reduce the film-forming rate of the third layer 1222 containing silicon on the surface of the substrate 10 where the Cl terminations 1230 are formed and in the vicinity of the entrance portion 1211 of the pattern 1210 of the trench structure.

By repeatedly performing the steps (a) through (f) described above a plurality number of times, it is possible to form the film on the surface of the pattern 1210 of the trench structure formed on the substrate 10.

Further, while the steps (a) through (f) described above are repeatedly performed the plurality number of times or while the step (a), the step (c) or the step (e) is performed, the support 440 connected to the rotational driving motor 430 via the rotation transmission belt 432 is rotationally driven by the rotational driving motor 430 to form the film.

When the source gas is supplied or when the reactive gas is supplied, the height (distance) of the substrate 10 with respect to the partition plate 203 is set such that the distance between the substrate 10 and the partition plate 203 is widened (that is, the widened gap G2 is formed) by lowering the substrate 10 as shown in FIG. 3C. On the other hand, when the film-forming inhibitory gas is supplied, the distance between the substrate 10 and the partition plate 203 is narrowed (that is, the narrowed gap G1 is formed) by elevating the substrate 10 as shown in FIG. 3B. In such a manner, the film is formed while the distance between the substrate 10 and the partition plate 203 is periodically changed between the narrowed gap G1 and the widened gap G2.

By reducing a film-forming rate of the first layer 1220 in the vicinity of the entrance portion 1211 of the pattern 1210 of the trench structure as described above, it is possible to form the first layer 1220 with a sufficient thickness in the vicinity of the bottom portion 1212 of the pattern 1210 of the trench structure, and it is also possible to improve a step coverage of the first layer 1220 in the pattern 1210 of the trench structure as compared with a case where the step of forming the Cl terminations 1230 are not performed.

That is, as shown in FIG. 13, by sequentially and repeatedly performing: stacking (or laminating) the third layer 1222 on the second layer 1221 (wherein the Cl terminations are formed on a part of the second layer 1221); converting the third layer 1222 into a silicon nitride layer to form the Cl terminations on a part of the silicon nitride layer; and newly stacking the third layer 1222 thereon, it is possible to stack the third layer 1222 with a thickness sufficient to form a signal circuit in the vicinity of the bottom portion 1212 of the pattern 1210 of the trench structure before the entrance portion 1211 of the pattern 1210 of the trench structure is blocked.

Further, in the present specification, the term “substrate” may refer to “a substrate itself” or may refer to “a substrate and a stacked structure (aggregated structure) of predetermined layers or films formed on a surface of the substrate”. That is, the term “substrate” may collectively refer to the substrate and the layers or the films formed on the surface of the substrate. In addition, in the present specification, the term “a surface of a substrate” may refer to “a surface (exposed surface) of a substrate itself” or may refer to “a surface of a predetermined layer or a film formed on the substrate, i.e. a top surface (uppermost surface) of the substrate as the stacked structure”.

In addition, in the present specification, the terms “substrate” and “wafer” may be used as substantially the same meaning.

Subsequently, a specific example of the film-forming process will be described with reference to a flow chart shown in FIG. 7A.

<Process Conditions Setting Step: S701>

First, the CPU 260a reads the process recipe and the related database stored in the memory 260c and sets process conditions. Instead of the memory 260c, the process recipe and the related database may be obtained via the network 263.

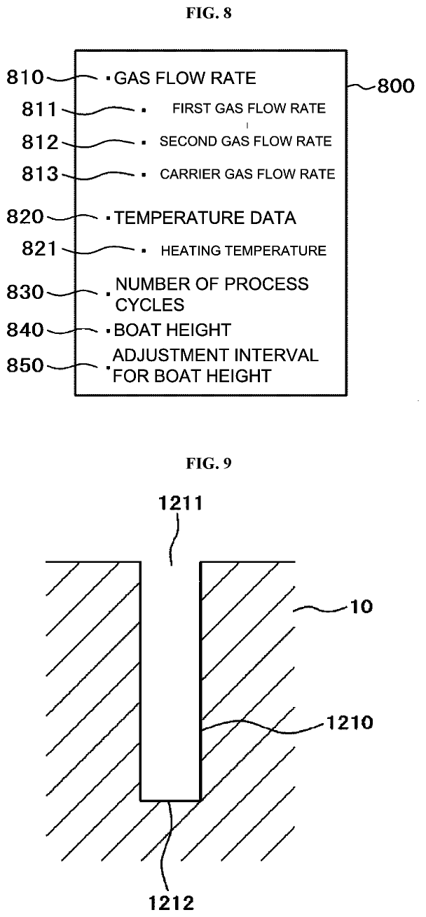

FIG. 8 schematically illustrates an example of a process recipe 800 read by the CPU 260a. The process recipe 800 may include main items such as a “gas flow rate” 810, a “temperature data” 820, the “number of process cycles” 830, a “boat height” 840 and an “adjustment interval” 850 for the boat height.

The gas flow rate 810 may include items such as a “first gas flow rate” 811, a “second gas flow rate” 812 and a “carrier gas flow rate” 813. However, in FIG. 8, a display of a “film-forming inhibitory gas flow rate” is omitted. The temperature data 820 may include an item such as a “heating temperature” 821 in the reaction tube 110 by the heater 101.

The boat height 840 may include items such as preset values of a minimum value (that is, the narrowed gap G1) and a maximum value (that is, the widened gap G2) of the distance between the substrate 10 and the partition plate 203 described with reference to FIGS. 3B and 3C.

The adjustment interval 850 for the boat height may include an item such as a switching time interval between a time duration of maintaining the distance between the substrate 10 and the partition plate 203 at the minimum value as shown in FIG. 3B and a time duration of maintaining the distance between the substrate 10 and the partition plate 203 at the maximum value as shown in FIG. 3C. That is, the film is formed on the substrate 10 by processing the substrate 10 while alternately switching between the case in which the distance between the surface of the substrate 10 and the partition plate 203 (that is, the position of the substrate 10 with respect to the position of the hole 121 of the gas supply nozzle 120) is set as shown in FIG. 3B and the case in which the distance between the surface of the substrate 10 and the partition plate 203 is set as shown in FIG. 3C. As a result, it is possible to form the film such that a flat thickness distribution of the film in which the thickness of the film formed on the central portion on the surface of the substrate 10 is substantially the same as that of the film formed on the outer peripheral portion on the surface of the substrate 10 can be obtained and such that the step coverage of the film inside the pattern 1210 of the trench structure formed on the substrate 10 is improved.

<Substrate Loading Step: S702>

In a state where the substrate support 300 is accommodated in the storage chamber 500, the vertical driving motor 410 is driven to rotationally drive the ball screw 411 so as to transfer the substrate support (boat) 300 by pitch feeding such that new substrates including a new substrate 10 are transferred (loaded or charged) into the substrate support 300 one by one through the substrate loading/unloading port 310 of the storage chamber 500. Hereinafter, the new substrates including the new substrate 10 may also be simply referred to as “new substrates 10” or “substrates 10”, and the new substrate 10 may also be simply referred to as the “substrate 10”.

The pattern 1210 of the trench structure whose cross-sectional shape is as shown in FIG. 9 is formed on a part of the substrate 10.

When the charging of the new substrates 10 into the substrate support 300 is completed, by driving the vertical driving motor 410 to rotationally drive the ball screw 411 in a state where the substrate loading/unloading port 310 is closed and an inside of the storage chamber 500 is hermetically sealed with respect to an outside of the storage chamber 500, the substrate support 300 is elevated. As a result, the substrate support 300 is transferred (loaded) into the reaction tube 110 from the storage chamber 500.

When the substrate support 300 is being loaded, the height of the substrate support 300 elevated by the vertical driving motor 410 is set based on the process recipe read in the step S701 such that a positional difference (in a height direction) between the substrate 10 accommodated in the substrate support 300 and an ejection position (which corresponds to the height of a front end of the nozzle 120) of the gas supplied into the reaction tube 110 through the nozzle 120 via a hole (not shown) provided in a tube wall of the reaction tube 110 can be set as shown in FIG. 3B or FIG. 3C.

<Pressure Adjusting Step: S703>

In a state where the substrate support 300 is loaded in the reaction tube 110, the inner atmosphere of the reaction tube 110 is vacuum-exhausted by the vacuum pump (not shown) through the exhaust pipe 130 such that an inner pressure of the reaction tube 110 reaches and is maintained at a desired pressure.

<Temperature Adjusting Step: S704>

In a state where the inner atmosphere of the reaction tube 110 is vacuum-exhausted by the vacuum pump (not shown), the heater 101 heats the reaction tube 110 based on the recipe read in the step S701 such that an inner temperature of the reaction tube 110 reaches and is maintained at a desired temperature. When heating the reaction tube 110, an amount of the electric current supplied to the heater 101 is feedback-controlled based on temperature information detected by a temperature sensor (not shown) such that a desired temperature distribution of the inner temperature of the reaction tube 110 can be obtained. The heater 101 continuously heats the reaction tube 110 until at least a processing of the substrate 10 is completed.

<Film-forming Step: S705>

Subsequently, in order to stack and form the layer containing silicon on the surface of the substrate 10 (including the inside of the pattern 1210 of the trench structure), the following detailed steps are performed as shown in FIG. 7B.

<Setting Distance between Substrate and Partition Plate to G2: S7051>

First, the relative position (height) of the surface of the substrate 10 accommodated in the substrate support 300 with respect to the hole 121 of the nozzle 120 and the partition plate 203 of the partition plate support 200 is adjusted such that the distance between the partition plate 203 and the substrate 10 is set to the widened gap G2 shown in FIG. 3C, which is relatively wide. However, when the distance between the partition plate 203 and the substrate 10 is set to the widened gap G2 in the temperature adjusting step S704, the height of the surface of the substrate 10 remains unchanged. Further, for example, the widened gap G2 is adjusted to a gap within a range from 14 mm to 30 mm. In the present specification, a notation of a numerical range such as “from 14 mm to 30 mm” means that a lower limit and an upper limit are included in the numerical range. Therefore, for example, the numerical range “from 14 mm to 30 mm” means a range equal to or higher than 14 mm and equal to or lower than 30 mm. The same also applies to other numerical ranges described herein.

The height of the surface of the substrate 10 is set by operating the boat vertical driver 420 provided with the linear actuator to drive the shaft 421 in the vertical direction based on the process recipe read in the step S701.

<Source Gas Supply Step (Supplying First Gas into Reaction Tube): S7052>

Subsequently, by rotationally driving the rotational driving motor 430 to rotate the support 440 via the rotation transmission belt 432, the partition plate support 200 and the substrate support 300 supported by the support 440 are rotated.

While the substrate support 300 is being rotated, a first gas serving as the source gas whose flow rate is adjusted is supplied into the reaction tube 110 through the hole 121 of the nozzle 120. Thereby, the first layer 1220 is formed on the surface of the substrate 10. A part of the source gas supplied into the reaction tube 110, which did not contribute to a reaction on the surface of the substrate 10, is exhausted through the exhaust pipe 130.

As a result, the source gas is supplied to the substrate 10 accommodated in the substrate support 300. The flow rate of the source gas to be supplied is adjusted by the mass flow controller (MFC) (not shown).

When supplying the source gas, the inert gas serving as the carrier gas is supplied into the reaction tube 110 together with the source gas, and is exhausted through the exhaust pipe 130.

For example, a chlorosilane-based gas such as monochlorosilane (SiH₃Cl, abbreviated as MCS) gas, dichlorosilane (SiH₂Cl₂, abbreviated as DCS) gas, trichlorosilane (SiHCl₃, abbreviated as TCS) gas, tetrachlorosilane (SiCl₄, abbreviated as STC) gas, hexachlorodisilane gas (Si₂Cl₆, abbreviated as HCDS) gas and octachlorotrisilane (Si₃Cl₈, abbreviated as OCTS) gas may be used as the source gas. Further, for example, a fluorosilane-based gas such as tetrafluorosilane (SiF₄) gas and difluorosilane (SiH₂F₂) gas, a bromosilane-based gas such as tetrabromosilane (SiBr₄) gas and dibromosilane (SiH₂Br₂) gas, or an iodine silane-based gas such as tetraiodide silane (SiI₄) gas and diiodosilane (SiH₂I₂) gas may be used as the source gas. Further, for example, an aminosilane-based gas such as tetrakis (dimethylamino) silane (Si[N(CH₃)₂]₄, abbreviated as 4DMAS) gas, tris (dimethylamino) silane (Si[N(CH₃)₂]₃H, abbreviated as 3DMAS) gas, bis (diethylamino) silane (Si[N(C₂H₅)₂]₂H₂, abbreviated as BDEAS) gas and bis (tertiarybutylamino) silane (SiH₂[NH(C₄H₉)]₂, abbreviated as BTBAS) gas may be used as the source gas. One or more of the gases described above may be used as the source gas.

Further, for example, nitrogen (N₂) gas may be used as the inert gas. Instead of the N₂ gas, a rare gas such as argon (Ar), helium (He) gas, neon (Ne) gas and xenon (Xe) gas may be used as the inert gas. One or more of the gases described above may be used as the carrier gas.

The carrier gas is supplied into the reaction tube 110 through the nozzle 120, and is exhausted through the exhaust pipe 130. When the carrier gas is supplied and exhausted, a temperature of the heater 101 is set such that, for example, a temperature of the substrate 10 is within a range from 250° C. to 550° C.

As described above, in a state where the distance between the substrate 10 and the partition plate 203 is increased to the widened gap G2 such that the distance between the substrate 10 and the partition plate 203 is widened, by supplying (or flowing) the first gas serving as the source gas between the substrate 10 and the partition plate 203, the flow velocity of the source gas flowing between the substrate 10 and the partition plate 203 becomes relatively slow.

As a result, the source gas is easily supplied to the vicinity of the bottom portion 1212 of the pattern 1210 of the trench structure, and as shown in FIG. 10, the first layer 1220 is formed by the source gas not only on the surface of the substrate 10 but also on a region including the bottom portion 1212 inside the pattern 1210 of the trench structure.

<Source Gas Exhaust Step (Exhausting First Gas from Reaction Tube): S7053>

After the first layer 1220 is formed on the bottom portion 1212 of the pattern 1210 of the trench structure of the substrate 10 by supplying the first gas serving as the source gas into the reaction tube 110 through the nozzle 120 for a predetermined time, a supply of the source gas is stopped. In the present step, the inner atmosphere of the reaction tube 110 is vacuum-exhausted by the vacuum pump (not shown) to remove a residual gas remaining in the reaction tube 110 such as the source gas which did not react or which contributed to the formation of the first layer 1220 out of the reaction tube 110.

When removing the residual gas, the inert gas serving as the carrier gas is continuously supplied into the reaction tube 110 through the nozzle 120. The carrier gas serves as a purge gas, which improves an efficiency of removing the residual gas remaining in the reaction tube 110 such as the source gas which did not react or which contributed to the formation of the first layer 1220 out of the reaction tube 110.

Further, for example, the nitrogen (N₂) gas or the rare gas such as argon (Ar), helium (He) gas, neon (Ne) gas and xenon (Xe) gas may be used as the purge gas.

<Performing a Predetermined Number of Times: Step S7054>

In the step S7054, it is determined whether or not a cycle in which the substeps of the step S705 (that is, the step S7051 through the step S7053 described above and a step S7055 through a step S7059) are sequentially performed in this order a predetermined number of times (n times). When it is determined that the cycle is performed the predetermined number of times, a step S706 is performed.

On the other hand, when it is determined that the cycle is not performed the predetermined number of times, the step S7055 is performed.

<Reactive Gas Supply Step (Supplying Second Gas into Reaction Tube): S7055>

After the residual gas in the reaction tube 110 is removed out of the reaction tube 110, while the substrate support 300 is being rotated by driving the rotational driving motor 430, the second gas serving as the reactive gas is supplied into the reaction tube 110 through the nozzle 120, and a part of the reactive gas which did not contribute to the reaction is exhausted through the exhaust pipe 130. Thereby, the reactive gas is supplied to the substrate 10. Specifically, a flow rate of the reactive gas to be supplied is adjusted by the mass flow controller (not shown). When supplying the reactive gas, the temperature of the heater 101 is set to substantially the same temperature as that of the heater 101 in the source gas supply step S7052.

In the present step, since the distance between the substrate 10 and the partition plate 203 is set to the widened gap G2 in the same manner as when the source gas is supplied (that is, set to the gap within a range from 14 mm to 30 mm), a flow velocity of the reactive gas flowing between the substrate 10 and the partition plate 203 becomes relatively fast. As a result, the reactive gas is supplied to the vicinity of the bottom portion 1212 of the pattern 1210 of the trench structure in the same manner as the source gas.

By supplying the reactive gas to the surface of the substrate 10 in a heated and activated state, the surface of the first layer 1220 (which is formed by the source gas on the surface of the substrate 10 and the inside of the pattern 1210 of the trench structure including the bottom portion 1212) is nitrided to form the second layer 1221 as shown in FIG. 12. Further, the NH terminations are formed on the surface of the second layer 1221.

For example, a hydrogen nitride-based gas such as diazene (N₂H₂) gas, ammonia (NH₃) gas, hydrazine (N₂H₄) gas, and N₃H₈ gas may be used as the reactive gas.

<Residual Gas Removing Step (Exhausting Second Gas from Reaction Tube): S7056>

After supplying the reactive gas into the reaction tube 110 through the nozzle 120 for a predetermined time, a supply of the reactive gas into the reaction tube 110 through the nozzle 120 is stopped. Then, the inner atmosphere of the reaction tube 110 is vacuum-exhausted by the vacuum pump (not shown) to remove a residual gas remaining in the reaction tube 110 such as the reactive gas which did not react and reaction by-products out of the reaction tube 110 in the same manners as in the source gas exhaust step S7053.

When removing the residual gas, the inert gas is supplied from the nozzle 120 into the reaction tube 110. The inert gas serves as the purge gas, which improves an efficiency of removing the residual gas remaining in the reaction tube 110 which did not react or which contributed to the formation of the second layer 1221 out of the reaction tube 110. For example, the same gas as the gas described in the source gas supply step S7052 may be used as the inert gas.

<Setting Distance between Substrate and Partition Plate to G1: S7057>

Subsequently, the position of the substrate 10 is elevated with respect to the partition plate 203 such that the distance between the partition plate 203 and the substrate 10 is set to the narrowed gap G1 shown in FIG. 3B, which is narrower than the widened gap G2. By operating the boat vertical driver 420 provided with the linear actuator to drive the shaft 421 upward based on the process recipe read in the step S701 and thereby switching (or alternately changing) the relative position (height) of the surface of the substrate 10 accommodated the substrate support 300 with respect to the hole 121 of the nozzle 120 and the partition plate 203 of the partition plate support 200 from a first height to a second height, the distance between the partition plate 203 and the substrate 10 is set to the narrowed gap G1. Further, for example, the narrowed gap G1 is adjusted to a gap within a range from 3 mm to 14 mm.

<Film-forming Inhibitory Gas Supply Step (Supplying Third Gas into Reaction Tube): S7058>

After the residual gas in the reaction tube 110 is removed out of the reaction tube 110, while the substrate support 300 is being rotated by driving the rotational driving motor 430, the third gas serving as the film-forming inhibitory gas is supplied into the reaction tube 110 through the nozzle 120, and a part of the film-forming inhibitory gas which did not contribute to the reaction is exhausted through the exhaust pipe 130. Thereby, the film-forming inhibitory gas is supplied to the substrate 10. Specifically, a flow rate of the film-forming inhibitory gas to be supplied is adjusted by the mass flow controller (not shown).

When supplying the film-forming inhibitory gas, the temperature of the heater 101 is set to substantially the same temperature as that of the source gas supply step S7052 and that of the reactive gas supply step S7055.

In the present step, since the distance between the substrate 10 and the partition plate 203 is set to be the narrowed gap G1 (which is narrower than the widened gap G2 when the source gas is supplied), the flow velocity of the film-forming inhibitory gas flowing between the substrate 10 and the partition plate 203 becomes slower than that of the source gas and that of the reactive gas. As a result, the film-forming inhibitory gas is less likely to be supplied to the vicinity of the bottom portion 1212 of the pattern 1210 of the trench structure as compared to the source gas and the reactive gas.

When the film-forming inhibitory gas is supplied in such a state, the film-forming inhibitory gas supplied to the surface of the substrate 10 reacts with the second layer 1221 formed on the surface of the substrate 10. Thereby, a layer of the Cl terminations 1230 is formed on the surface of the substrate 10.

Further, a gas such as hydrogen chloride (HCl) gas and chlorine (Cl₂) gas may be used as the film-forming inhibitory gas.

On the other hand, in the pattern 1210 of the trench structure, the film-forming inhibitory gas merely reaches the vicinity of the entrance portion 1211 and does not reach the bottom portion 1212 of the pattern 1210 of the trench structure. As a result, as shown in FIG. 12, the Cl terminations 1230 are not formed on the bottom portion 1212 of the pattern 1210 of the trench structure, and therefore the NH terminations on the surface of the second layer 1221 are exposed.

<Residual Gas Removing Step (Exhausting Third Gas from Reaction Tube): S7059>

After the Cl terminations 1230 are formed in the portion of the pattern 1210 of the trench structure, a supply of the film-forming inhibitory gas into the reaction tube 110 through the nozzle 120 is stopped. Then, the inner atmosphere of the reaction tube 110 is vacuum-exhausted by the vacuum pump (not shown) to remove a residual gas remaining in the reaction tube 110 such as the film-forming inhibitory gas which did not react or which contributed to the formation of the Cl terminations 1230 and reaction by-products out of the reaction tube 110 in the same manners as in the source gas exhaust step S7053.

When removing the residual gas, the carrier gas is supplied from the nozzle 120 into the reaction tube 110. The carrier gas serves as the purge gas, which improves an efficiency of removing the residual gas remaining in the reaction tube 110 such as the film-forming inhibitory gas which did not react or which contributed to the formation of the Cl terminations 1230 and the reaction by-products out of the reaction tube 110.

<Returning to Step S7051>

After the residual gas remaining in the reaction tube 110 such as the film-forming inhibitory gas and the reaction by-products are exhausted out of the reaction tube 110, the step S7051 is performed again to lower the position of the substrate 10 with respect to the partition plate 203 such that the distance between the partition plate 203 and the substrate 10 is set to the widened gap G2.

Subsequently, the step S7052 is performed such that the third layer 1222 is formed by the source gas on the surface of the substrate 10 including the bottom portion 1212 of the pattern 1210 of the trench structure.

In the present step, the Cl terminations 1230 formed on the surface of the substrate 10 and in the vicinity of the entrance portion 1211 of the pattern 1210 of the trench structure acts as the inhibitor (film-forming inhibitory layer) against the formation of the layer containing silicon formed by the source gas.

Since the Cl terminations 1230 acts as the inhibitor against the formation of the layer containing silicon, the film-forming rate of the third layer 1222 is slow in the vicinity of the entrance portion 1211 of the pattern 1210 of the trench structure and on the surface of the substrate 10 where the Cl terminations 1230 are formed. As a result, it is possible to suppress and delay a blockage in the vicinity of the entrance portion 1211 of the pattern 1210 of the trench structure by the third layer 1222 which has grown.

On the other hand, in the vicinity of the bottom portion 1212 of the pattern 1210 of the trench structure where the Cl terminations 1230 are not formed and therefore the NH terminations are exposed, the third layer 1222 is formed without reducing the film-forming rate.

When the third layer 1222 is formed in the pattern 1210 of the trench structure in a state where the Cl terminations 1230 are not formed, a growth rate of the third layer 1222 at the entrance portion 1211 is generally faster than the growth rate of the third layer 1222 in the vicinity of the bottom portion 1212. Therefore, in a case where the bottom portion 1212 of the pattern 1210 of the trench structure is deep, the entrance portion 1211 of the pattern 1210 of the trench structure is blocked by the third layer 1222 before the third layer 1222 in the vicinity of the bottom portion 1212 is sufficiently formed.

On the other hand, according to the present disclosure, as described above, the Cl terminations 1230 are formed on the surface of the substrate 10 and in the vicinity of the entrance portion 1211 of the pattern 1210 of the trench structure. Therefore, as shown in FIG. 13, it is possible to form the third layer 1222 with a thickness sufficient to form a circuit pattern on an inner surface of the pattern 1210 of the trench structure including the bottom portion 1212 before the vicinity of the entrance portion 1211 of the pattern 1210 of the trench structure is blocked. Thus, it is possible to form the third layer 1222 with a sufficient step coverage on the inner surface of the pattern 1210 of the trench structure as compared with a case where the Cl terminations 1230 are not formed.

By delaying a growth of the third layer 1222 in the vicinity of the entrance portion 1211 of the pattern 1210 of the trench structure and growing the third layer 1222 in the vicinity of the bottom portion 1212 of the pattern 1210 of the trench structure as described above, it is possible to improve the step coverage of the pattern 1210 of the trench structure as compared with the case where the Cl terminations 1230 are not formed.

<Performing a Predetermined Number of Times: Step S7054>

The step S7054 is performed again. In the step S7054, it is determined whether or not the cycle in which the substeps of the step S705 described above (that is, the step S7051 through the step S7053 and the step S7055 through the step S7059) are sequentially performed in this order the predetermined number of times (n times). Thereby, by sequentially and repeatedly performing: newly forming the third layer 1222 by stacking on the second layer 1221 (wherein the NH terminations are formed on the surface thereof and partially covered with the Cl terminations 1230) in the vicinity of the portion of the pattern 1210 of the trench structure; forming the Cl terminations on a part of the third layer 1222; and newly stacking the third layer 1222 thereon, it is possible to stack the third layer 1222 with the thickness sufficient to form the signal circuit in the vicinity of the bottom portion 1212 of the pattern 1210 of the trench structure before the entrance portion 1211 of the pattern 1210 of the trench structure is blocked. It is preferable that the cycle described above is repeatedly performed a plurality number of times, for example, about 10 times to 80 times, and more preferably, about 10 times to 15 times.

While switching (or alternately changing) the distance between the partition plate 203 and the substrate 10 between the widened gap G2 when forming the first layer 1220 and the second layer 1221 and the narrowed gap G1 when forming the Cl terminations 1230 by driving the shaft 421 in the vertical direction by operating the boat vertical driver 420 provided with the linear actuator based on the process recipe read in the step S701 as described above, the steps including the source gas supply step S7052, the reactive gas supply step S7055 and the film-forming inhibitory gas S7058 are repeatedly performed. Thereby, it is possible to form the third layer 1222 in the portion of the pattern 1210 of the trench structure of the substrate 10.

Further, while the present embodiments are described by way of an example in which the substrate support 300 in which the substrate 10 is accommodated is rotated by the rotational driving motor 430 in the source gas supply step S7052, the reactive gas supply step S7055 and the film-forming inhibitory gas S7058, the substrate support 300 may be continuously rotated during the residual gas exhaust steps (that is, the steps S7053, S7056 and S7059).

<After-Purge Step (Purge And Returning to Atmospheric Pressure Step): S706>

After repeatedly performing a series of steps in the step S705 the predetermined number of times, the N₂ gas is supplied into the reaction tube 110 through the nozzle 120, and is exhausted through the exhaust pipe 130. The N₂ gas serves as the purge gas, and the inner atmosphere of the reaction tube 110 is purged with the N₂ gas serving as the inert gas. Thereby, the residual gas remaining in the reaction tube 110 and the reaction by-products remaining in the reaction tube 110 are removed out of the reaction tube 110. Then, the N₂ gas is filled in the reaction tube 110 until the inner pressure of the reaction tube 110 reaches an atmospheric pressure.

<Substrate Unloading Step: S707>

Thereafter, the vertical driving motor 410 is driven to rotate the ball screw 411 in an opposite direction such that the partition plate support 200 and the substrate support 300 are lowered from the reaction tube 110. As a result, the substrate support 300 accommodating the substrate 10 on which the film of a predetermined thickness is formed on the surface thereof is transferred (unloaded) to the storage chamber 500.

<Temperature Lowering Step: S708>

In the storage chamber 500, after the substrate 10 with the film formed on the surface thereof is transferred (discharged) out of the storage chamber 500 from the substrate support (boat) 300 through the substrate loading/unloading port 310, an inner temperature of the storage chamber 500 is lowered while a heating by the heater 101 is stopped. Thereby, the processing of the substrate 10 is completed.

While the present embodiments are described by way of an example in which the third layer 1222 is formed by stacking on the portion of the pattern 1210 of the trench structure of the substrate 10, the present embodiments are not limited thereto. For example, it is possible to form a film such as a SiO₂ film, a Si₃N₄ (silicon nitride) film and a TiN (titanium nitride) film by applying the present embodiments. In addition, the present embodiments may also be applied to form another film other than the films described above. For example, the present embodiments may also be applied to form a film containing an element such as tungsten (W), tantalum (Ta), ruthenium (Ru), molybdenum (Mo), zirconium (Zr), hafnium (Hf), aluminum (Al), silicon (Si), germanium (Ge) and gallium (Ga), a film containing an element of the same family as the elements described above, a compound film of one or more elements described above and nitrogen (that is, a nitride film) or a compound film of one or more elements described above and oxygen (that is, an oxide film). Further, when forming the films described above, a halogen-containing gas or a gas containing at least one of a halogen element, an amino group, a cyclopentane group, oxygen (O), carbon (C) or an alkyl group may be used.

According to the technique of the present disclosure, by delaying the growth of the third layer 1222 in the vicinity of the entrance portion 1211 of the pattern 1210 of the trench structure and growing the third layer 1222 in the vicinity of the bottom portion 1212 of the pattern 1210 of the trench structure, it is possible to improve the step coverage of the pattern 1210 of the trench structure as compared with the case where the Cl terminations 1230 are not formed.

In addition, since the Cl terminations 1230 are formed by supplying the film-forming inhibitory gas in the heated state, it is possible to omit a plasma generating structure for exciting the film-forming inhibitory gas, and it is possible to improve the step coverage of the pattern 1210 of the trench structure by using an apparatus such as the substrate processing apparatus 100 with a relatively simple configuration.

While the technique of the present disclosure is described by way of an example in which the film-forming process is performed, the technique of the present disclosure is not limited thereto. For example, the technique of the present disclosure may also be applied when the etching process is performed.

When the technique of the present disclosure is applied to the etching process, by supplying an etching gas in the state in which the distance between the substrate 10 and the partition plate 203 above the substrate 10 is narrowed as shown in FIG. 3B by driving the boat vertical driver 420 provided with the linear actuator to drive the shaft 421 in the vertical direction, it is possible to perform an “E process” of a DED (Deposition-Etch-Deposition) process. In the present specification, the term “DED process” refers to a process of repeatedly performing the film-forming process (“Deposition”) and the etching process (“Etch”) to form a predetermined film. The “E process” described above refers to the etching process.

In addition, by widening the distance between the substrate 10 and the partition plate 203 above the substrate 10 while the etching gas is being supplied (in the state shown in FIG. 3C), it is possible to adjust a uniformity of etching within the surface of the substrate 10.

According to some embodiments of the present disclosure, it is possible to improve the step coverage of the pattern formed on the substrate.

What is claimed is:

1. A substrate processing method comprising:
(a) accommodating a substrate retainer in a process chamber, wherein the substrate retainer comprises:
a substrate support capable of supporting a substrate; and
a partition plate support capable of supporting an upper partition plate provided above the substrate supported by the substrate support;
(b) setting a distance between the substrate and the upper partition plate to a first gap;
(c) supplying a first gas to the substrate through a gas supply port in a state where the distance between the substrate and the upper partition plate is maintained at the first gap;
(d) setting the distance between the substrate and the upper partition plate to a second gap; and
(e) supplying a second gas to the substrate through the gas supply port in a state where the distance between the substrate and the upper partition plate is maintained at the second gap.

2. The substrate processing method of claim 1, wherein, in (c), the first gap is wider than the second gap.

3. The substrate processing method of claim 1, wherein, in (e), the second gap is narrower than the first gap.

4. The substrate processing method of claim 2, wherein, in (c), the substrate is arranged below the gas supply port.

5. The substrate processing method of claim 3, wherein, in (e), the substrate is arranged above the gas supply port.

6. The substrate processing method of claim 1, wherein a plurality of substrates comprising the substrate are supported by the substrate support to be arranged in a vertical direction at a predetermined interval therebetween, and
wherein a plurality of upper partition plates comprising the upper partition plate are supported by the partition plate support between the plurality of substrates, respectively.

7. The substrate processing method of claim 1, wherein the second gas comprises a film-forming inhibitory gas.

8. The substrate processing method of claim 1, further comprising
(f) supplying a third gas to the substrate through the gas supply port between (c) and (e) while maintaining the distance between the substrate and the upper partition plate at the first gap.

9. The substrate processing method of claim 8, wherein the first gas comprises a source gas, and the third gas comprises a reactive gas.

10. The substrate processing method of claim 1, wherein a trench is formed on the substrate.

11. The substrate processing method of claim 10, wherein a film-forming inhibitory layer is formed at an entrance portion of the trench by a film-forming inhibitory gas.

12. The substrate processing method of claim 11, wherein the film-forming inhibitory gas comprises a chlorine-containing gas.

13. The substrate processing method of claim 1, wherein the distance between the substrate and the upper partition plate is adjusted to the first gap in (b) and the distance between the substrate and the upper partition plate is adjusted to the second gap in (d) by a driver capable of adjusting the distance between the substrate and the upper partition plate.

14. A method of manufacturing a semiconductor device, comprising:
(a) accommodating a substrate retainer in a process chamber, wherein the substrate retainer comprises:
a substrate support capable of supporting a substrate; and
a partition plate support capable of supporting an upper partition plate provided above the substrate supported by the substrate support;
(b) setting a distance between the substrate and the upper partition plate to a first gap;
(c) supplying a first gas to the substrate at the first gap through a gas supply port in a state where the distance between the substrate and the upper partition plate is maintained at the first gap;
(d) setting the distance between the substrate and the upper partition plate to a second gap; and
(e) supplying a second gas to the substrate at the second gap through the gas supply port in a state where the distance between the substrate and the upper partition plate is maintained at the second gap.

15. A substrate processing apparatus comprising:
a process chamber in which a substrate retainer is accommodated, wherein the substrate retainer comprises:
a substrate support capable of supporting a substrate; and
a partition plate support capable of supporting an upper partition plate provided above the substrate supported by the substrate support;
a driver capable of adjusting a distance between the substrate and the upper partition plate by vertically driving either the substrate support or the partition plate support;
a gas supplier through which a gas is supplied to the substrate accommodated in the process chamber; and
a controller configured to be capable of controlling the driver and the gas supplier to perform:
(a) accommodating the substrate retainer in the process chamber;
(b) setting the distance between the substrate and the upper partition plate to a first gap;
(c) supplying a first gas to the substrate through a gas supply port provided at the gas supplier in a state where the distance between the substrate and the upper partition plate is maintained at the first gap;
(d) setting the distance between the substrate and the upper partition plate to a second gap; and
(e) supplying a second gas to the substrate at the second gap through the gas supply port provided at the gas supplier in a state where the distance between the substrate and the upper partition plate is maintained at the second gap.

16. The substrate processing apparatus of claim 15, wherein a plurality of substrates comprising the substrate are supported by the substrate support to be arranged in a vertical direction at a predetermined interval therebetween, and
wherein a plurality of upper partition plates comprising the upper partition plate are supported by the partition plate support between the plurality of substrates, respectively.
